(19) United States
(12) Patent Application Publication
(10) Pub. No.: US 2024/0092973 A1
(43) Pub. Date: Mar. 21, 2024

(54) POLYIMIDE PRECURSOR, RESIN COMPOSITION, PHOTOSENSITIVE RESIN COMPOSITION, METHOD FOR MANUFACTURING PATTERNED CURED FILM, CURED FILM, INTERLAYER INSULATING FILM, COVER COAT LAYER, SURFACE-PROTECTIVE FILM, AND ELECTRONIC COMPONENT

(71) Applicant: HD Microsystems, Ltd., Tokyo (JP)

(72) Inventors: Naoto NAGAMI, Hitachi-shi (JP); Daisaku MATSUKAWA, Hitachi-shi (JP); Nobuyuki SAITO, Hitachi-shi (JP); Atsutaro YOSHIZAWA, Hitachi-shi (JP)

(21) Appl. No.: 17/766,800

(22) PCT Filed: Oct. 7, 2019
(86) PCT No.: PCT/JP2019/039543

§ 371 Date: Apr. 6, 2022

(51) Int. Cl. C08G 73/10; C08J 3/28; C08L 79/08

(52) U.S. Cl. CPC C08G 73/1003; C08G 73/1046; C08J 3/28; C08L 79/08

(57) ABSTRACT

A polyimide precursor having a structural unit represented by the following formula (1):

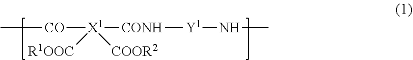

### TECHNICAL FIELD

The invention relates to a polyimide precursor; a resin composition, a photosensitive resin composition, a method for manufacturing a patterned cured film, a cured film, an interlayer insulating film, a cover coat layer, a surface protective film, and an electronic component.

### BACKGROUND ART

For a surface protective film and an interlayer insulating film of a semiconductor device, polyimide having excellent heat resistance, electrical properties, mechanical properties and the like at the same time, have been used (see, e.g., Patent Document 1).

In recent years, with a high-performance enhancement of electronic apparatus and dramatic progress of network technology, capacity enlargement and speedup of data transmission are rapidly advancing, and the signal frequency handled tends to be higher in frequency. Generally, the higher the frequency becomes, the lower the signal transmissibility is made, and therefore, the demand for a material having low transmission loss is increasing. However, the conventional polyimide disclosed in Patent Document 1 or the like, could not sufficiently meet such a demand.

### RELATED ART DOCUMENTS

### Patent Documents

[Patent Document 1] JPH08-337652A

[Patent Document 2] WO 2018/179382A1

### SUMMARY OF THE INVENTION

It is an object of the invention to provide a polyimide precursor capable of providing a material having low transmission loss even in a high frequency band.

As a result of extensive studies focusing on the relationship between the structure and the polarity of the polyimide precursor, the inventors have found that a low transmission loss can be realized even in a high frequency band by adopting a structural unit having a specific structure in the polyimide precursor, whereby completing the invention.

According to the invention, the following polyimide precursor and the like are provided.

1. A polyimide precursor having a structural unit represented by the following formula (1):

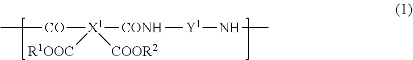

wherein in the formula (1), X¹ is a tetravalent group having one or more aromatic groups; and when X¹ is a group represented by the following formula (11), Z³ is a divalent group other than a carbonyl group;

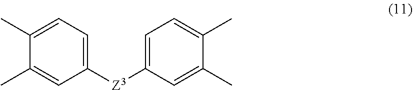

Y¹ is a divalent group obtained by linking one or more kinds of groups selected from the group consisting of divalent groups represented by each of the following formulas (21) to (24);

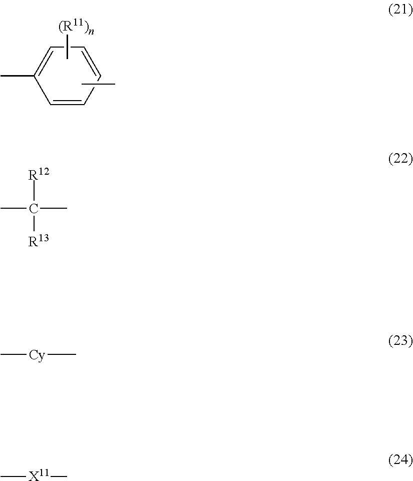

wherein in the formula (21), R¹¹ is an aliphatic hydrocarbon group including 1 to 4 carbon atoms, or a halogenated aliphatic hydrocarbon group including 1 to 4 carbon atoms; and n is an integer of 0 to 4;
wherein in the formula (22), R¹² and R¹³ are independently a hydrogen atom, an aliphatic hydrocarbon group including 1 to 4 carbon atoms, or a halogenated aliphatic hydrocarbon group including 1 to 4 carbon atoms;
wherein in the formula (23), Cy is a cyclic aliphatic hydrocarbon group including 3 to 10 carbon atoms; and
wherein in the formula (24), X¹¹ is an oxygen atom or a sulfur atom;
when in Y¹, the number of divalent group represented by the formula (21) contained in Y¹ is e, the number of divalent group represented by the formula (22) is f, the number of divalent group represented by the formula (23) is g, and the number of divalent group represented by the formula (24) is h, e≥1, f≥0, g≥0, and h≥0, and is e+f+g+h≥4;
R¹ and R² are independently a hydrogen atom, a group represented by the following formula (2), or an aliphatic hydrocarbon group including 1 to 4 carbon atoms;

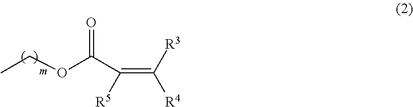

wherein in the formula (2), R³ to R⁵ are independently a hydrogen atom or an aliphatic hydrocarbon group including 1 to 4 carbon atoms, and m is an integer of 1 to 10; and
a —COOR¹ group and a —CO— group are in ortho-position to each other, and a —COOR² group and a —CONH— group are in ortho-position to each other.
   2. The polyimide precursor according to 1, wherein Y¹ comprises the divalent group represented by the formula (21) and the divalent group represented by the formula (22).
   3. The polyimide precursor according to 1 or 2, wherein Y¹ comprises the divalent group represented by the formula (21) and the divalent group represented by the formula (24).
   4. The polyimide precursor according to any one of 1 to 3, wherein Y¹ comprises the divalent group represented by the formula (21), the divalent group represented by the formula (22), and the divalent group represented by the formula (24).
   5. The polyimide precursor according to any one of 1 to 4, wherein in the formula (1), e≥3 (e is 3 or more).
   6. The polyimide precursor according to any one of 1 to 5, wherein in the formula (1), e≥3 (e is 3 or more) and f≥2 (f is 2 or more).
   7. The polyimide precursor according to any one of 1 to 6, wherein in the formula (1), e≥3 (e is 3 or more) and h≥2 (h is 2 or more).
   8. The polyimide precursor according to any one of 1 to 7, wherein in the formula (1), e≥4 (e is 4 or more).
   9. The polyimide precursor according to any one of 1 to 8, wherein in the formula (1), e+f+g+h≥5 (the sum of e, f, g and h is 5 or more).
   10. The polyimide precursor according to any one of 1 to 9, wherein in the formula (21), n=0 (n is 0).
   11. The polyimide precursor according to any one of 1 to 10, wherein in the formula (22), R¹² and R¹³ are independently a methyl group or a trifluoromethyl group.
   12. The polyimide precursor according to any one of 1 to 11, wherein in the formula (24), X¹¹ is an oxygen atom.
   13. The polyimide precursor according to any one of 1 to 12, wherein Y¹ comprises a divalent group represented by the following formula (31) or (32):

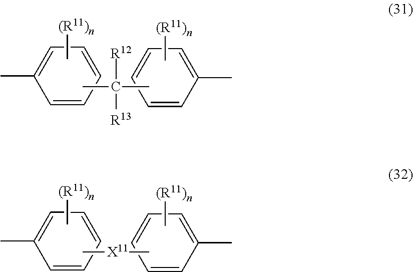

wherein in the formulas (31) and (32), R¹¹, R¹², R¹³, and X¹¹ are as defined in each of the formulas (21), (22), and (24).
   14. The polyimide precursor according to any one of 1 to 13, wherein Y¹ comprises any one of divalent groups represented by each of the following formulas:

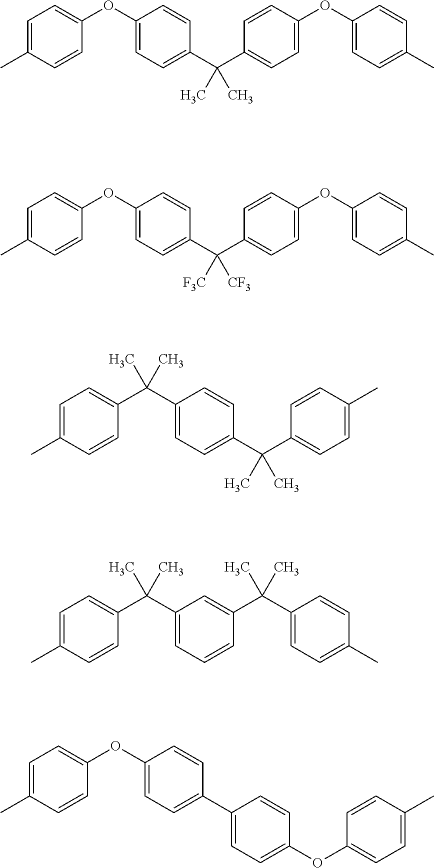

15. The polyimide precursor according to any one of 1 to 14, wherein X¹ is any one of tetravalent groups represented by each of the following formulas:

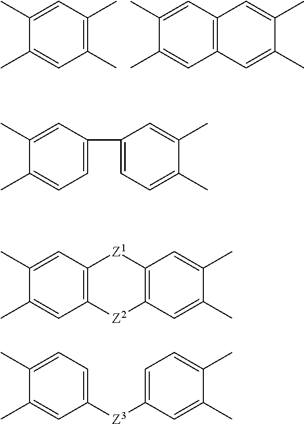

wherein in the formula, Z¹ and Z² are independently a divalent group does not conjugate with the benzene ring bonded thereto, or a single bond; and Z³ is a divalent group other than a carbonyl group.
   16. The polyimide precursor according to any one of 1 to 15, wherein Z³ comprises an ether bond (—O—) or a sulfide bond (—S—).
   17. The polyimide precursor according to any one of 1 to 16, wherein Z³ comprises a divalent group having an aromatic hydrocarbon group.
   18. The polyimide precursor according to any one of 1 to 17, wherein Z³ comprises a divalent group represented by —O—Ar—O—, —S—Ar—S—, or —COO—Ar—OOC—, where Ar is a divalent group comprising a benzene ring, a divalent group comprising a naphthalene ring, or a divalent group comprising an anthracene ring.
   19. The polyimide precursor according to any one of 1 to 18, wherein in the formula (1), R¹ and R² are independently a hydrogen atom or an aliphatic hydrocarbon group including 1 to 4 carbon atoms.
   20. The polyimide precursor according to any one of 1 to 18, wherein in the formula (1), at least one of R¹ and R² is a monovalent group represented by the formula (2).
   21. A resin composition comprising the polyimide precursor according to any one of 1 to 20.
   22. A photosensitive resin composition comprising:
(A) the polyimide precursor according to any one of 1 to 20;
(B) a polymerizable monomer, and
(C) a photopolymerization initiator.
   23. A method for manufacturing a patterned cured film comprising steps of:
applying the photosensitive resin composition according to 22 on a substrate, followed by drying to form a photosensitive resin film
subjecting the photosensitive resin film to pattern-exposure to obtain a resin film;
developing the resin film having undergone the pattern-exposure using an organic solvent to obtain a patterned resin film; and
heat-treating the patterned resin film.
   24. The method for manufacturing a patterned cured film according to 23, wherein the heat treatment is conducted at a temperature of 200° C. or less.
   25. A cured film obtained by curing the photosensitive resin composition according to 22.
   26. The cured film according to 25, which is a patterned cured film.
   27. An interlayer insulating film, a cover coat layer, or a surface protective film formed by using the cured film according to 25 or 26.
   28. An electronic component comprising the interlayer insulating film, the cover coat layer, or the surface protective film according to 27.

According to the invention, a polyimide precursor capable of providing a material having low transmission loss even in a high frequency band can be provided.

### BRIEF DESCRIPTION OF THE DRAWINGS

FIG. 1 is a manufacturing process diagram of an electronic component according to an embodiment of the invention.

### MODE FOR CARRYING OUT THE INVENTION

Hereinafter; embodiments of the polyimide precursor, the resin composition, the photosensitive resin composition, the method for manufacturing the patterned cured film, the cured film, the interlayer insulating film, the cover coat layer, the surface protective film, and the electronic component of the invention will be described in detail. However, the invention is not limited to the following embodiments.

In the specification, “A or B” may include either one of A and B, or may also include both of A and B. The term “step” herein includes not only an independent step, but also a step, if an intended action of the step is achieved, even when the step is not clearly distinguishable from the other steps.

A numerical range represented by using “to” indicates the range including numerical values described before and after “to” as a minimum value and a maximum value, respectively. Moreover, when a plurality of materials corresponding to one component exists in the composition, unless otherwise specified, a content of the component in the composition herein means a total amount of the plurality of materials existing in the composition. Further, unless otherwise specified, materials listed as examples may be used alone or in combination of two or more.

The term “(meth)acrylic group:” means an “acrylic group” and a “methacrylic group”

### [Polyimide Precursor]

The polyimide precursor of the invention has a structural unit represented by the formula (1).

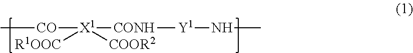

In the formula (1), X¹ is a tetravalent group having one or more aromatic groups; and when X¹ is a group represented by the following formula (11), Z³ is a divalent group other than a carbonyl group;

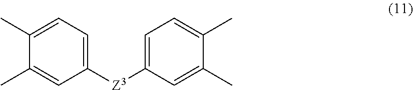

Y¹ is a divalent group obtained by linking one or more kinds of groups selected from the group consisting of divalent groups represented by each of the following formulas (21) to (24);

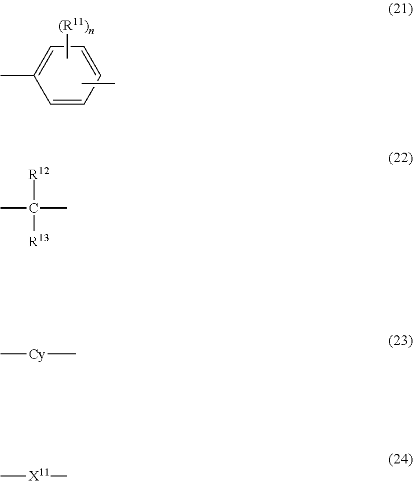

in the formula (21), R¹¹ is an aliphatic hydrocarbon group including 1 to 4 carbon atoms, or a halogenated aliphatic hydrocarbon group including 1 to 4 carbon atoms; and n is an integer of 0 to 4;
in the formula (22), R¹² and R¹³ are independently a hydrogen atom, an aliphatic hydrocarbon group including 1 to 4 carbon atoms, or a halogenated aliphatic hydrocarbon group including 1 to 4 carbon atoms;
in the formula (23), Cy is a cyclic aliphatic hydrocarbon group including 3 to 10 carbon atoms;
in the formula (24), X¹¹ is an oxygen atom or a sulfur atom;
when in Y¹, the number of divalent group represented by the formula (21) contained in Y¹ is e, the number of divalent group represented by the formula (22) is f, the number of divalent group represented by the formula (23) is g, and the number of divalent group represented by the formula (24) is h, e≥1 (e is 1 or more), f≥0 (f is 0 or more), g≥0 (g is 0 is more), and h≥0 (h is 0 or more), and e+f+g+h≥4 (the sum of e, f, g and h is 4 or more);
R¹ and R² are independently a hydrogen atom, a group represented by the following formula (2), or an aliphatic hydrocarbon group including 1 to 4 carbon atoms;

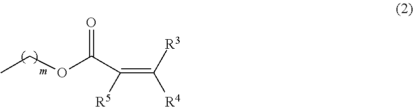

in the formula (2), R³ to R⁵ are independently a hydrogen atom or an aliphatic hydrocarbon group including 1 to 4 carbon atoms, and m is an integer of 1 to 10; and
a —COOR¹ group and a —CO— group are in ortho-position to each other, and a —COOR² group and a CONH— group are in ortho-position to each other.

All the divalent groups represented by each of the formulas (21) to (24) used as Y¹ can suppress the polarity of the main-chain of the polyimide precursor to be low. Further, introduction into Y¹ of such partial structures in a continuous manner in a certain length (e+f+g+h≤4) allows to give a polyimide with a low distribution density of the highly polar imide rings. The polyimide precursor of the invention can provide a material with a lowered transmission loss even in a high frequency band along with the combination of the above actions. Specifically, use of the polyimide precursor of the invention allows to provide a resin material with a lowered relative dielectric constant (Dk) and a lowered dielectric loss tangent (Dt) even in a high frequency band (e.g., 10 GHz or higher).

In the formula (1), Y¹ contains the divalent group represented by the formula (21) among the formulas (21) to (24), and may further contain any of the divalent groups represented by each of the formulas (22) to (24).

Y¹ may contain the divalent group represented by the formula (21) and the divalent group represented by the formula (22), may contain the divalent group represented by the formula (21) and the divalent group represented by the formula (24), or may contain the divalent group represented by the formula (21), the divalent group represented by the formula (22), and the divalent group represented by the formula (24).

The number of the divalent group represented by the formula (21) contained in Y¹, that is indicated with “e”, may be 1 or more, 2 or more, or 3 or more, and may be 10 or less, or 8 or less, for example. The number of e can be 1, 2, 3, 4, 5, 6, 7, 8, 9, or 10.

The number of e is preferably 3 or more, and may be 4 or more.

In the divalent group represented by the formula (21) in Y¹, n=0 (n is preferably 0) (that is, the divalent group represented by the formula (21) is an unsubstituted phenylene group).

In the divalent group represented by the formula (22) in Y¹, R¹² and R¹³ are preferably independently a methyl group or a trifluoromethyl group.

The number of the divalent group represented by the formula (22) contained in Y¹, that is indicated with “f” may be 0 or more, 1 or more, 2 or more, or 3 or more, and may be 10 or less, or 8 or less, for example. The number of f can be 1, 2, 3, 4, 5, 6, 7, 8, 9, or 10.

In the divalent group represented by the formula (23) in Y¹, Cy is preferably a divalent cycloalkane including 3 to 8 carbon atoms, and more preferably a divalent cycloalkane including 3 to 6 carbon atoms.

The number of the divalent group represented by the formula (23) contained in Y¹, that is indicated with “g” may be 0 or more, 1 or more, 2 or more, or 3 or more, and may be 10 or less, or 8 or less, for example. The number of g can be 1, 2, 3, 4, 5, 6, 7, 8, 9, or 10.

In the divalent group represented by the formula (24) of Y¹, X¹¹ is preferably an oxygen atom.

The number of the divalent group represented by the formula (24) contained in Y¹, that is indicated with “h” may be 0 or more, 1 or more, 2 or more, or 3 or more, and may be 10 or less, or 8 or less, for example. The number of h can be 1, 2, 3, 4.5, 6, 7, 8, 9, or 10.

When Y¹ contains the divalent group represented by the formula (21) and the divalent group represented by the formula (22), the number of e may be 3 or more and the number of f may be 2 or more.

When Y¹ contains the divalent group represented by the formula (21) and the divalent group represented by the formula (24), the number of e may be 3 or more and the number of h may be 2 or more.

In the formula (1), the sum of e, f, g, and h (e+f+g+h) may be 5 or more, or 6 or more. Although there is no particular upper limit of e+f+g+h, for example, 20 or less is preferable, 15 or less is more preferable, from the viewpoint of the photosensitive characteristics.

Y¹ preferably contains a divalent group represented by the following formula (31) or (32).

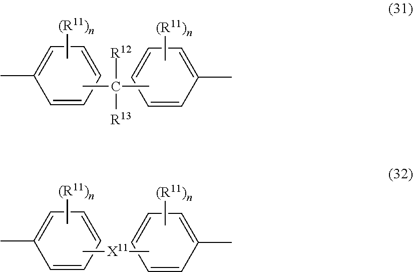

In the formulas (31) and (32), R¹¹, n, R¹², R¹³, and X¹¹ are as defined in each of the formulas (21), (22), and (24).

Y¹ may contain a divalent group represented by the following formula (33).

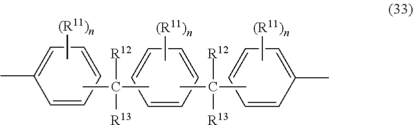

In the formula (33), R¹¹, n, R¹², R¹³, and X¹¹ are as defined in each of the formulas (21), (22), and (24).

Y¹ may contain two or more of the divalent groups represented by the formula (32).

Y¹ may contain a divalent group represented by the following formula (34) or (35).

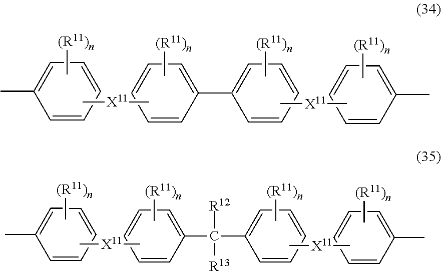

In the formulas (34) and (35), R¹¹, n, R¹², R¹³, and X¹¹ are as defined in each of the formulas (21), (22), and (24).

Y¹ preferably contains any of divalent groups represented by each of the following formulas, or is any of the divalent groups represented by each of the following formulas.

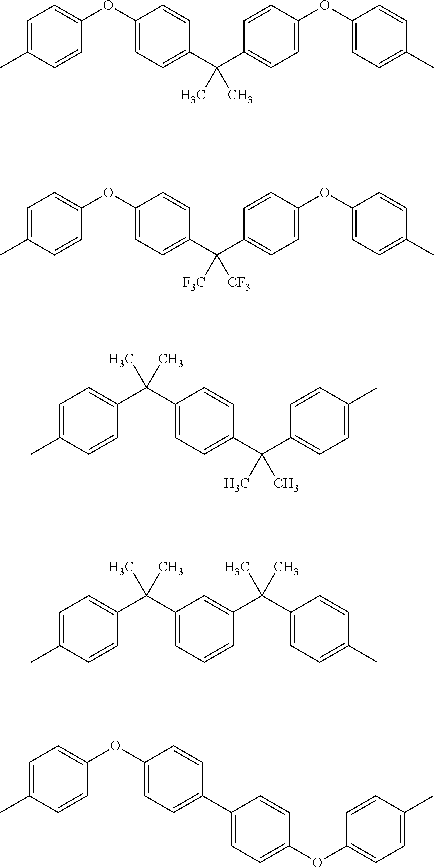

In a tetravalent group having one or more (preferably one to three, more preferably one or two) aromatic groups for X¹ in the formula (1), the aromatic group may be an aromatic hydrocarbon group (for example, including 6 to 20 carbon atoms), and may be an aromatic heterocyclic group (for example, including 5 to 20 atoms). The aromatic hydrocarbon group is preferred.

Examples of the aromatic hydrocarbon group for X¹ in the formula (1) include divalent to tetravalent (divalent, trivalent, or tetravalent) groups derived from a benzene ring, divalent to tetravalent groups derived from naphthalene, divalent to tetravalent groups derived from perylene, and the like.

X¹ is preferably any of tetravalent groups represented by each of the following formulas.

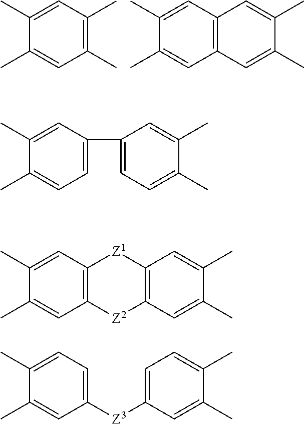

In the formula, Z¹ and Z² are independently a divalent group which does not conjugate with the benzene rings bonded thereto, or a single bond; and Z³ is a divalent group other than a carbonyl group.

The divalent group for Z¹ and Z² is preferably —O—, —S—, a methylene group, a bis(trifiuoromethyprnethylene group, or a difluoromethylene group, and more preferably —O—.

In one embodiment, Z³ contains an ether bond (—O—) or a sulfide bond (—S—).

In the other embodiment, Z³ preferably contains a divalent group derived from an aromatic hydrocarbon, and preferably contains one or more groups selected from the group consisting of a divalent group derived from a benzene ring, a divalent group derived from a naphthalene ring, and a divalent group derived from an anthracene ring.

Examples of the divalent group for Z³ include —O—Ar—O—, —S—Ar—S—, —COO—Ar—OOC—, and the like. Here, Ar is a divalent group derived from a benzene ring, a divalent group derived from a naphthalene ring, or a divalent group derived from an anthracene ring.

Z³ is not a carbonyl group, but may be a divalent group containing a carbonyl group along with another divalent group. When Z³ is a carbonyl group, inferior transmission loss is given. In the case where Z³ is not a carbonyl group or contains a carbonyl group, the transmission loss is improved. Also, when Z³ contains a carbonyl group along with another divalent group, the transmission loss is improved. Although the reason why such an action is exerted is not necessarily clear, it is estimated as follows. In a polyimide obtained by imidization of a polyimide precursor (ring-closing reaction), a carbonyl group and an imide ring increase the polarity of the main-chain of the polyimide, so that it causes of the increased transmission loss. Here, In the case where Z³ is not a carbonyl group or does not contain a carbonyl group, the polarity of the main-chain is lowered, whereby the transmission loss is suppressed to be low. In addition, in the case where Z³ contains a carbonyl group and another divalent group, the length of the main-chain is increased by the length of the other divalent group, so that the distribution density of the imide ring can be lowered, thereby the transmission loss is suppressed to be low.

In one embodiment, R¹ and R² are independently a hydrogen atom or an aliphatic hydrocarbon group including 1 to 4 carbon atoms. This embodiment is suitable when a polyimide precursor having a structural unit represented by the formula (1) is used as a polyimide precursor for a non-photosensitive resin composition, and in this case, The group represented by the formula (2) does not necessarily have to be included as R¹ and R².

In another embodiment, R¹ and R² are independently a hydrogen atom, a group represented by the following formula (2), or an aliphatic hydrocarbon group including 1 to 4 carbon atoms, and at least one of R¹ and R² is a monovalent group represented by the formula (2). This embodiment is suitable when a polyimide precursor having a structural unit represented by the formula (1) is used as a polyimide precursor for a photosensitive resin composition, and in this case, both of R¹ and R² are more preferably monovalent groups represented by the formula (2).

Examples of the aliphatic hydrocarbon group including 1 to 4 (preferably 1 or 2) carbon atoms for R¹ and R² include a methyl group, an ethyl group, an n-propyl group, a 2-propyl group, an n-butyl group, and the like.

Examples of the aliphatic hydrocarbon group including 1 to 3 (preferably 1 or 2) carbon atoms for R³ to R⁵ in the formula (2) include a methyl group, an ethyl group, an n-propyl group, a 2-propyl group, and the like. A methyl group is preferable.

The content of the structural unit represented by the formula (1) is preferably 50 mol % or more, more preferably 80 mol % or more, and still more preferably 90 mol % or more, based on the total moles of the structural units in the component (A). The upper limit is not particularly limited and may be 100 mol %.

The polyimide precursor having a structural unit represented by the formula (1) is, for example, a polyamic acid obtained by reacting a tetracarboxylic dianhydride represented by the following formula (22) with a diamino compound represented by the following formula (23) in an organic solvent such as N-methyl-2-pyrrolidone (hereinafter referred to as “NMP”). Further, it can be a whole or partially esterified polyamic acid obtained by adding a compound represented by the following formula (24) to such a polyamic acid, followed by reaction in an organic solvent to introduce an ester group corresponding to the formula (2).

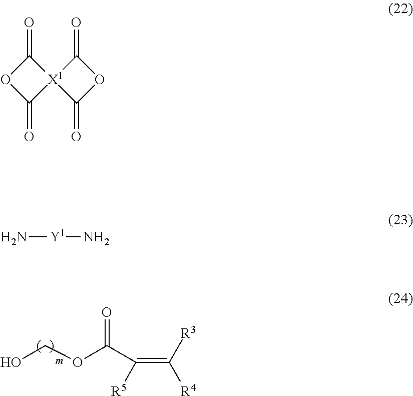

In the formula (22), X¹ is as defined in the formula (1); in the formula (23), Y¹ is as defined in the formula (1); in the formula (24), R³ to R⁵ and m are as defined in the formula (2).

The tetracarboxylic dianhydride represented by the formula (22) and the diamino compound represented by the formula (23) may be used one kind alone or two or more kinds, respectively.

The content of the structural unit represented by the formula (1) is preferably 50 mol % or more, more preferably 80 mol % or more, and still more preferably 90 mol % or more, based on the total moles of the constitutional unit of the polyamide precursor. The upper limit is not particularly limited and may be 100 mol %.

When the polyimide precursor having a structural unit represented by the formula (1) is used as a polyimide precursor for a photosensitive resin composition, the proportion of the carboxy group esterified with the group represented by the formula (2), based on the total moles of carboxy groups and carboxy esters in the polyimide precursor is preferably 50 mol % or more, more preferably 60 to 100 mol %, and still more preferably 70 to 90 mol %. The upper limit is not particularly limited, and may be 100 mol %.

Although there is no particular limitation on the molecular weight of the component (A), it is preferably 10,000 to 50,000 in the weight-average molecular weight, more preferably 15,000 to 45,000, and still more preferably 18,000 to 40,000.

The weight-average molecular weight of the component (A) can be measured by, for example, a gel permeation chromatography method, and can be calculated by conversion using a standard polystyrene calibration curve.

### [Resin Composition]

The resin composition (curable resin composition) of the invention contains the polyamide precursor of the invention described above.

The resin composition include a non-photosensitive resin composition and a photosensitive resin composition. The photosensitive resin composition may be any of a positive photosensitive resin composition and a negative photosensitive resin composition.

The resin composition of the invention can be suitably used as a material for an electronic component.

### [Photosensitive Resin Composition]

The photosensitive resin composition of the invention contains the above-described polyamide precursor of the invention (hereinafter, also referred to as “component (A)”), (B) a polymerizable monomer (hereinafter, also referred to as “component (B)”), and (C) a photopolymerization initiator (hereinafter, also referred to as “component (C)”) and may also contain the other components. Hereinafter, each of the components other than the component (A) will be described.

### Component (B): Polymerizable Monomer

The component (B) crosslinks with the component (A) or the components (B) polymerize with each other, to form a crosslinked network. The component (B) preferably has a group containing a polymerizable unsaturated double bond, and preferably has a group containing two to four (preferably two or three) polymerizable unsaturated double bonds, in order for increasing the crosslinking density, for increasing the photosensitivity and for suppressing the swelling of the pattern after development. The group for the component (B) is preferably a (meth)acrylic group or an allyl group, from the viewpoint that they can be polymerized by means of a photopolymerization initiator.

Examples of the component (B) include, for example, diethylene glycol diacrylate, triethylene glycol diacrylate, tetraethylene glycol diacrylate, diethylene glycol dimethacrylate, triethylene glycol dimethacrylate, tetraethylene glycol dimethacrylate, 1,4-butanediol diacrylate, 1,6-hexanediol diacrylate, 1,4-butanediol dimethacrylate, 1,6-hexanediol dimethacrylate, trimethylolpropane diacrylate, trimethylolpropane triacrylate, trimethylolpropane dimethacrylate, trimethylolpropane trimethacrylate, pentaerythritol triacrylate, pentaerythritol tetraacrylate, pentaerythritol trimethacrylate, pentaerythritol tetramethacrylate, tetramethylolmethane tetraacrylate, tetramethylolmethane tetramethacrylate, dipentaerythritol hexaacrylate, dipentaerythritol hexamethacrylate, ethoxylated pentaerythritol tetraacrylate, ethoxylated isocyanuric acid triacrylate, ethoxylated isocyanuric acid trimethacrylate, acryloyloxyethyl isocyanurate, methacryloyloxyethyl isocyanurate, and the like, and among these, tetraethylene glycol dimethacrylate, pentaerythritol tetraacrylate, and ethoxylated pentaerythritol tetraacrylate are preferred.

The content of the component (B) is preferably 1 to 50 parts by mass, based on 100 parts by mass of the component (A). From the viewpoint of enhancing hydrophobicity of the cured product, it is more preferably 3 to 45 parts by mass, and still more preferably 5 to 40 parts by mass.

Within the above range, a practical relief pattern is easily obtained, and residue after development of an unexposed portion is easily suppressed.

### Component (C): Photopolymerization Initiator

As the component (C), for example, benzophenone derivatives such as benzophenone, methyl o-benzoylbenzoate, 4-benzoyl-4′-methyldiphenyl ketone, dibenzyl ketone, fluorenone; acetophenone derivatives such as 2,2′-diethoxyacetophenone, 2-hydroxy-2-methyl propiophenone, 1-hydroxycyclohexyl phenyl ketone; thioxanthone derivatives such as thioxanthone, 2-methylthioxanthone, 2-isopropylthioxanthone, diethylthioxanthone; benzyl derivatives such as benzyl, benzyl dimethylketal, benzyl-β-methoxyethyl acetal; benzoin derivatives such as benzoin, benzoin methyl ether; oxime esters such as 1-phenyl-1,2-butanedione-2-(o-methoxycarbonyl)oxime, 1-phenyl-1,2-propanedione-2-(o-methoxycarbonyl)oxime, 1-phenyl-1,2-propanedione-2-(o-ethoxycarbonyl)oxime, 1-phenyl-1,2-propanedione-2-(o-benzoyl)oxime, 1,3-diphenylpropanetrione-2-(o-ethoxycarbonyl)oxime, 1-phenyl-3-ethoxypropanetrione-2-(o-benzoyl)oxime, ethanone, 1-[9-ethyl-6-(2-methylbenzoyl)-9H-carbazol-3-yl]-, 1-(O-acetyloxime), the compound represented by the following formula; and the like are preferably mentioned, but are not limited thereto. Oxime esters are preferable from the viewpoint of photosensitivity.

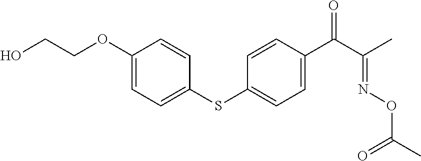 [SMILES: CC(=O)O/N=C(\C)C(=O)c1ccc(Sc2ccc(OCCO)cc2)cc1]

The content of the component (C) is preferably 0.1 to 20 parts by mass, more preferably 0.1 to 10 parts by mass, and still more preferably 0.1 to 5 parts by mass, based on 100 parts by mass of the component (A). Within the above range, the photocrosslinking tends to occur uniformly in the film thickness direction, and a practical relief pattern can be easily obtained.

### (Solvent)

Examples of the solvent include N-methyl-2-pyrrolidone, γ-butyrolactone, ethyl lactate, propylene glycol monomethyl ether acetate, benzyl acetate, n-butyl acetate, ethoxyethylpropionate, 3-methylmethoxypropionate, N,N-dimethylformamide, N,N-dimethylacetamide, dimethylsulfoxide, hexamethylphosphorylamide, tetramethylene sulfone, cyclohexanone, diethyl pentanone, diethyl ketone, diisobutyl ketone, methyl amyl ketone, and N-dimethylmorpholine, and are not particularly limited as long as other components can be sufficiently dissolved.

Among these, N-methyl-2-pyrrolidone, γ-butyrolactone, ethyl lactate, propylene glycol monomethyl ether acetate, N,N-dimethylformamide, and N,N-dimethylacetamide are preferably used from the viewpoint of excellent solubility of each component and coating property at the time of forming a photosensitive resin film.

The content of the solvent is not particularly limited, and is generally 50 to 1000 parts by mass, based on 100 parts by mass of the component (A).

### (Other Components)

The photosensitive resin composition of the invention may further contain a coupling agent (adhesive aid), a surfactant or a leveling agent, a rust inhibitor, a polymerization inhibitor, and the like.

### Coupling Agent

In general, the coupling agent reacts and crosslinks with the component (A) during the heat treatment after development, or the coupling agents themselves polymerize with each other during the heat treatment step. As a result, the adhesiveness between the cured product to be obtained and a substrate can be increased.

Examples of preferred silane coupling agents include compounds hosing an urea bond (—NH—CO—NH—). By using such a silane coupling agent, even when curing is performed at a low temperature of 200° C. or lower, the adhesiveness to the substrate can be further enhanced.

A compound represented by the following formula (61) is more preferable from the viewpoint of excellent adhesiveness being exhibited when curing is performed at a low temperature.

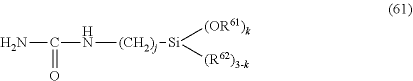

In the formula (61), R⁶¹ and R⁶² are independently an alkyl group including 1 to 5 carbon atoms; j is an integer of 1 to 10, and k is an integer of 1 to 3.

Specific examples of the compound represented by the formula (61) include ureidomethyltrimethoxysilane, ureidomethyltriethoxysilane, 2-ureidoethyltrimethoxysilane, 2-ureidoethyltriethoxysilane, 3-ureidopropyltrimethoxysilane, 3-ureidopropyltriethoxysilane, 4-ureidobutyltrimethoxysilane, 4-ureidobutyltriethoxysilane, and the like. 3-ureidopropyltriethoxysilane is preferable.

As the silane coupling agent, a silane coupling agent having a hydroxy group or a glycidyl group may be used. When a silane coupling agent having a hydroxy group or a glycidyl group and a silane coupling agent having a urea bond in the molecular are used in combination, the adhesiveness of the cured product to the substrate when cured at a low temperature can be further increased.

Examples of the silane coupling agent having a hydroxy group or a glycidyl group include methylphenylsilanediol, ethylphenylsilanediol, n-propylphenylsilanediol, isopropylphenylsilanediol, n-butylphenylsilanediol, isobutylphenylsilanediol, tert-butylphenylsilanediol, diphenylsilanediol, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl-n-propylphenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, phenylsilanetriol, 1,4-bis(trihydroxysilyl)benzene, 1,4-bis(methyldihydroxysilyl)benzene, 1,4-bis(ethyldihydroxysilyl)benzene, 1,4-bis(propyldihydroxysilyl)benzene, 1,4-bis(butyldihydroxysilyl)benzene, 1,4-bis(dimethylhydroxysilyl)benzene, 1,4-bis(diethylhydroxysilyl)benzene, 1,4-bis(dipropylhydroxysilyl)benzene, 1,4-bis(dibutylhydroxysilyl)benzene, a compound represented by the following formula (62), and the like. Among these, a compound represented by the following formula (62) is particularly preferable in order to further increase the adhesiveness to the substrate.

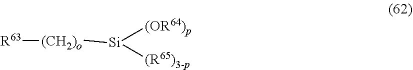

In the formula (62), R⁶³ is a monovalent organic group having a hydroxy group or a glycidyl group; R⁶⁴ and R⁶⁵ are independently an alkyl group including 1 to 5 carbon atoms; o is an integer of 1 to 10, and p is an integer of 1 to 3.

Examples of the compound represented by the formula (62) include hydroxymethyltrimethoxysilane, hydroxymethyltriethoxysilane, 2-hydroxymethyltriethoxysilane, 2-hydroxyethyltriethoxysilane, 3-hydroxypropyltrimethoxysilane, 3-hydroxypropyltriethoxysilane, 4-hydroxybutyltrimethoxysilane, 4-hydroxybutyltriethoxysilane, glycidoxymethyltrimethoxysilane, glycidoxymethyltriethoxysilane, 2-glycidoxyethyltrimethoxysilane, 2-glycidoxyethyltriethoxysilane, 3-glycidoxypropyltrimethoxysilane, 3-glycidoxypropyltriethoxysilane, and 4-glycidoxybutyltrimethoxysilane, 4-glycidoxybutyltriethoxysilane, and the like.

The silane coupling agent having a hydroxy group or a glycidyl group preferably further contains a group having a nitrogen atom, and preferably a silane coupling agent further having an amino group or an amide bond.

Examples of the silane coupling agents further having an amino group include bis(2-hydroxymethyl)-3-aminopropyltriethoxysilane, bis(2-hydroxymethyl)-3-aminopropyltrimethoxysilane, bis(2-glycidoxymethyl)-3-aminopropyltriethoxysilane, and bis(2-hydroxymethyl)-3-aminopropyltrimethoxysilane.

Examples of the silane coupling agents having an amide bond include a compound represented by the following formula (63) and the like.

R⁶⁶—(CH₂)_{q}—CO—NH—(CH₂)ᵢ—Si(OR⁶⁷)₃ (63)

In the formula (63), R⁶⁶ is a hydroxy group or a glycidyl group, q and r are independently an integer of 1 to 3, and R⁶⁷ is a methyl group, an ethyl group, or a propyl group.

When a silane coupling agent is used, the content of the silane coupling agent is preferably 0.1 to 20 parts by mass, more preferably 0.3 to 10 parts by mass, and still more preferably 1 to 10 parts by mass, based on 100 parts by mass of the component (A).

### (Surfactant or Leveling Agent)

By containing a surfactant or a leveling agent, the curable resin composition can improve coating property (e.g., suppression of striation (unevenness in film thickness)) and developability.

Examples of the surfactant or the leveling agent include polyoxyethylene lauryl ether, polyoxyethylene stearyl ether, polyoxyethylene oleyl ether, polyoxyethylene octyl phenol ether, and the like. As examples of commercially available products, trade names “Megaface F171”, “Megaface F173”, and “Megaface R-08” (these are manufactured by DIC Corporation), trade names “Fluorad FC430”, and “Fluorad FC431” (these are manufactured by Sumitomo 3M Limited), trade names of organosiloxane polymer “KP341”, “KBM303”, “KBM403”, and “KBM803” (these are manufactured by Shin-Etsu Chemical Industry Co., Ltd), and the like can be mentioned.

When the surfactant or the leveling agent is contained, the content of the surfactant or the leveling agent is preferably 0.01 to 10 parts by mass, more preferably 0.05 to 5 parts by mass, and still more preferably 0.05 to 3 parts by mass, based on 100 parts by mass of the component (A).

### (Rust Inhibitor)

By containing a rust inhibitor, the curable resin composition can suppress composition and prevent discoloration of copper and copper alloys.

Examples of the rust inhibitor include triazole derivatives, tetrazole derivatives and the like.

When the rust inhibitor is used, the content of the rust inhibitor is preferably 0.01 to 10 parts by mass, more preferably 0.1 to 5 parts by mass, and more preferably 0.5 to 3 parts by mass, based on 100 parts by mass of the component (A).

### (Polymerization Inhibitor)

When the curable resin composition contains a polymerization inhibitor, good storage stability can be ensured.

Examples of the polymerization inhibitor include a radical polymerization inhibitor, a radical polymerization retarder, and the like.

Examples of the polymerization inhibitor include p-methoxyphenol, diphenyl-p-benzoquinone, benzoquinone, hydroquinone, pyrogallol, phenothiazine, resorcinol, orthodinitrobenzene, paradinitrobenzene, methadinitrobenzene, phenanthraquinone, N-phenyl-2-naphthylamine, Cupferron, 2,5-toluquinone, tannic acid, parabenzylaminophenol, nitrosamines, and the like.

When the polymerization inhibitor is contained, the content of the polymerization inhibitor is preferably 0.01 to 30 parts by mass, more preferably 0.01 to 10 parts by mass, and still more preferably 0.05 to 5 parts by mass, based on 100 parts by mass of the component (A), from the viewpoint of storage stability of the photosensitive resin composition and heat resistance of the cured product to be obtained.

The photosensitive resin composition of the invention may consist essentially of the components (A) to (C), and optionally contain a component selected from a solvent, a coupling agent, a surfactant, a leveling agent, a rust inhibitor and a polymerization inhibitor The photosensitive resin composition may contain other unavoidable impurities within a range of not impairing the effect of the invention.

For example, 80% by mass or more, 90% by mass or more, 95% by mass or more, 98% by mass or more, 99% by mass or more, 99.5% by mass or more, 99.9% by mass or more, or 100% by mass of the photosensitive resin composition of the invention may be occupied by the component (A) to (C), or may be occupied by the component (A) to (C) and an optional component selected from a solvent, a coupling agent, a surfactant, a leveling agent, a rust inhibitor, and a polymerization inhibitor.

### [Cured Product]

The cured product of the invention can be obtained by curing the resin composition of the invention. The cured product of the invention may be used as a patterned cured film or as a pattern-less cured film. The thickness of the cured film of the invention is preferably 5 to 20 μm.

### [Method for Manufacturing Patterned Cured Film]

The method for manufacturing a patterned cured film of the invention includes a step of applying the above-mentioned photosensitive resin composition on a substrate, followed by drying to form a photosensitive resin film, a step of subjecting the photosensitive resin film to pattern-exposure to obtain a resin film, a step of developing the resin film having undergone the pattern-exposure using an organic solvent to obtain a patterned resin film, and a step of heat-treating the patterned resin film. Thus, a patterned cured film can be obtained.

A method for manufacturing a cured product without a pattern includes, for example, the above-described step to form a photosensitive resin film and the above-described step of heat-treating. Further, it may include a step of subjecting to exposure.

Examples of the substrate include a glass substrate, semiconductor substrates such as an Si substrate (silicon wafer), metal oxide insulator substrates such as a TiO₂ substrate and a SiO₂ substrate, silicon nitride substrates, a copper substrate, copper alloy substrates, and the like.

The application method is not particularly limited, but can be performed using a spinner or the like.

The drying can be performed using a hot plate, an oven, or the like.

The drying is preferably conducted at a temperature of 90 to 150° C., and more preferably 90 to 120° C., from the viewpoint of ensuring good dissolution contrast.

The drying is preferably conducted for 30 seconds to 5 minutes.

The drying may be performed two or more times.

As a result, a photosensitive resin film can be obtained by forming the above-mentioned photosensitive resin composition into a film shape.

The film thickness of the photosensitive resin film is preferably 5 to 100 μm, more preferably 6 to 50 μm, and still more preferably 7 to 30 μm.

In the pattern-exposure, exposure is performed through a photomask with a predetermined pattern.

Examples of the active rays to irradiate include ultraviolet rays such as an i-line and a broadband UV (BB), visible rays, and radiation rays, and is preferably the i-line.

As the exposure apparatus, a parallel exposure machine, a projection exposure machine, a stepper, a scanner exposure machine, or the like can be used.

As a result of development, a resin film formed in a pattern (patterned resin film) can be obtained. Generally, when a negative photosensitive resin composition is used, unexposed portions are removed with a developer.

As an organic solvent used as the developer, a good solvent for the photosensitive resin film can be used alone, or an appropriate mixture of a good solvent and a poor solvent for the photosensitive resin film can be used.

Examples of the good solvent include N-methyl-2-pyrrolidone, N-acetyl-2-pyrrolidone, dimethylacetamide, N,N-dimethylformamide, dimethylsulfoxide, γ-butyrolactone, α-acetyl-γ-butyrolactone, cyclopentanone, cyclohexanone, and the like.

Examples of the poor solvent include toluene, xylene, methanol, ethanol, isopropanol, propylene glycol monomethyl ether acetate, propylene glycol monomethyl ether, water, and the like.

A surfactant may be added to the developer The surfactant is preferably added in an amount of 0.01 to 10 parts by mass and more preferably of 0.1 to 5 parts by mass, with respect to 100 parts by mass of the developer.

The development can be performed, for example, twice as long as the time until the photosensitive resin film is completely dissolved from when it is immersed in the developer.

The time for development varies depending on the component (A) used, but is preferably 10 seconds to 15 minutes, more preferably 10 seconds to 5 minutes, and more preferably 20 seconds to 5 minutes, tom the viewpoint of productivity.

After the development, washing may be performed with a rinse solution.

Examples of the rinse solution include distilled water, methanol, ethanol, isopropanol, toluene, xylene, propylene glycol monomethyl ether acetate, propylene glycol monomethyl ether, and the like. The rinse solution may be used alone or as a mixture as appropriate, or may be used in a stepwise combination.

A patterned cured product can be obtained by heat-treating the patterned resin film.

The polyimide precursor of the component (A) undergoes a ring-closing reaction during a step of heat-treatment, and generally becomes the corresponding polyimide.

The heat treatment is performed preferably at a temperature of 250° C. or lower, more preferably of 120 to 250° C., and still more preferably of 200° C. or lower, or of 140 to 200° C.

Within the above range, damage to the substrate and the device can be suppressed to a small level, the device can be produced with a high yield, and energy saving of the process can be realized.

The time for the heat treatment is preferably 5 hours or less, more preferably 30 minutes to 3 hours. Within the above range, the crosslinking reaction or the ring closure reaction can sufficiently proceed.

The atmosphere during the heat treatment may be an air atmosphere or an inert atmosphere such as nitrogen, but from the viewpoint of preventing the patterned resin film from oxidation, the atmosphere is preferably a nitrogen atmosphere.

Examples of devices used for the heat treatment include a quartz tube oven, a hot plate, a rapid thermal annealing, a vertical diffusion furnace oven, an infrared curing oven, an electron beam curing oven, a microwave curing oven and the like.

### Interlayer Insulating Film, Cover Coat Layer, Surface Protective Film, and Electronic Component

The cured product of the invention can be used as a passivation film, a buffer coat film, an interlayer insulating film, a cover coat layer, a surface protective film, or the like.

With the use of one or more selected from the group consisting of the passivation film, the buffer coat film, the interlayer insulating film, the cover coat layer, the surface protective film, and the like, highly reliable electronic components such as semiconductor devices, multilayer wiring boards, various electronic devices, and laminated devices (such as multi-die fan-out wafer level packages) can be manufactured.

An example of a manufacturing process of a semiconductor apparatus which is an electronic component of the invention will be described with reference to Figures.

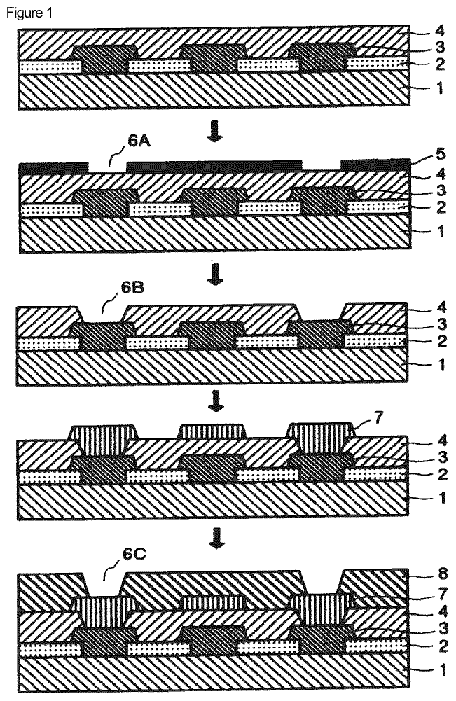

FIG. 1 is a manufacturing process diagram of a semiconductor apparatus having a multilayer wiring structure which is an electronic component according to one embodiment of the invention.

In FIG. 1, a semiconductor substrate 1 such as a Si substrate having a circuit device is covered with a protective film 2 such as a silicon oxide film except a predetermined portion of the circuit device, and a first conductor layer 3 is formed on the exposed circuit device. Thereafter, an interlayer insulating film 4 is formed on the semiconductor substrate 1.

Next, a photosensitive resin layer 5 formed from a material such as a chlorinated rubber-based resin, or a phenolic novolac-based resin, is formed on the interlayer insulating film 4, and a window 6A is provided by a known photolithography technique, so that a predetermined portion of the interlayer insulating film 4 is exposed.

The interlayer insulating film 4 with the window 6A exposed is selectively etched to provide a window 6B.

Next, the photosensitive resin layer 5 is removed by using an etchant that corrodes the photosensitive resin layer 5 but does not corrode the first conductive layer 3 exposed from the windows 6B.

Further, a second conductive layer 7 is formed by using a known photolithography technique and electrically connected to the first conductive layer 3.

In the case of forming a multilayer wiring structure of three or more layers, each layer can be formed by repeating the above steps.

Next, by using the above-mentioned photosensitive resin composition, a window 6C is opened by pattern-exposure, and a surface protective film 8 is formed. The surface protective film 8 protects the second conductive layer 7 from external stress, an a ray, or the like, and the resulting semiconductor device is excellent in reliability.

In the above example, it is also possible to form the interlayer insulating film using the photosensitive resin composition of the invention.

### EXAMPLES

Hereinafter, the invention will be described more specifically with reference to Examples and Comparative Examples. The invention is not limited to the following Examples.

### Measurement or Estimation of Weight-average Molecular Weight

For each of polyimide precursors obtained in the following Synthesis Examples and Synthesis Comparative Examples, measurement or estimation of weight-average molecular weight was performed by the following manner.

### (Estimation of Weight-average Molecular Weight)

The weight-average molecular weight was estimated based on the charged molar ratio of a raw amine component and a raw acid component at the time of synthesis of the polyimide precursor; each molecular weight thereof, a synthesis method, and synthesis conditions.

### (Measurement of Weight-average Molecular Weight)

The weight-average molecular weight (measured value) is determined by using a gel permeation chromatography (GPC) method and using a standard polystyrene conversion under the following conditions.

The weight-average molecular weight was measured using a solution of 0.5 mg of the polyimide precursor A1 in 1 mL of solvent [tetrahydrofuran (THF)/dimethylformamide (DMF)=1/1 (volume ratio)].
Measuring instrument: Detector L4000UV manufactured by Hitachi, Ltd.
Pumps: L6000 manufactured by Hitachi, Ltd.
   C-R4A Chromatopac manufactured by Shimadzu Corporation
Measuring conditions: two columns of Gelpack GL-S300MDT-5
Eluent: THF/DMF=1/1 (volume ratio)
   LiBr (0.03 mol/L), H₃PO₄ (0.06 mol/L)
Flow rate: 1.0 mL/min, detector: UV 270 nm

Materials used in the following Synthesis Examples and Synthesis Comparative Examples are shown below.

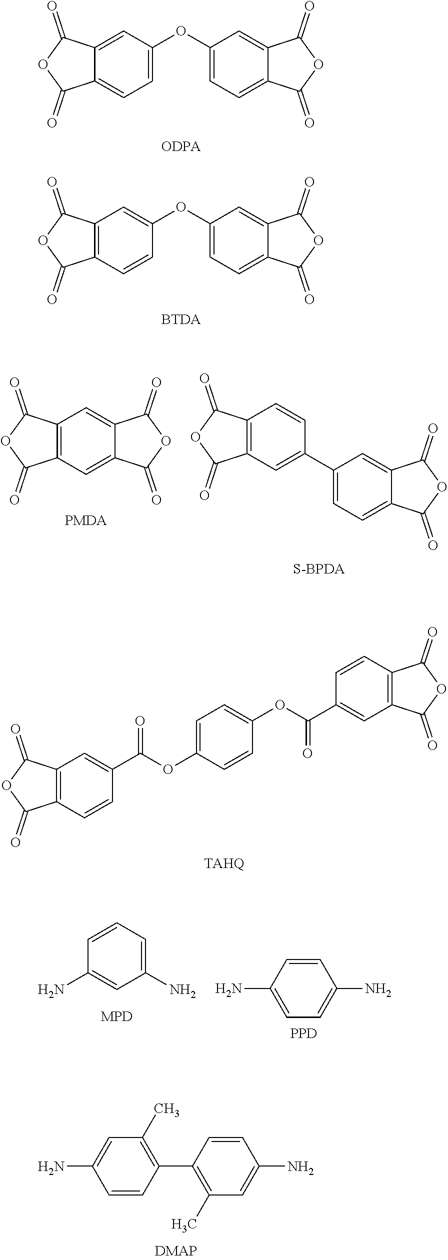

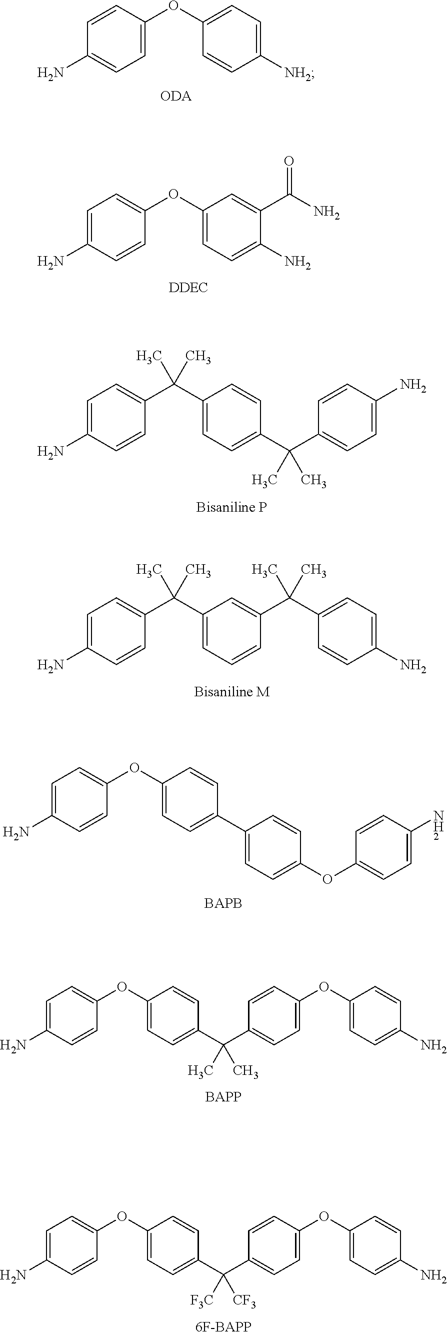

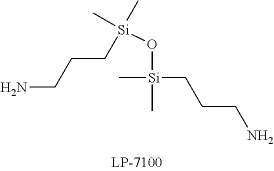

### Synthesis Example 1 (Synthesis of Polyimide Precursor A1)

5.00 g of 3,3′,4,4′-diphenylether tetracarboxylic dianhydride (ODPA) was dissolved in 64.0 g of N-methyl-2-pyrrolidone (NMP). 6.29 g of 2,2-bis[4-(4-aminophenoxy)phenyl]propane (BAPP) was added thereto, and then the mixture was stirred at room temperature (23° C., the same applies hereafter) for 3 hours to obtain a polyimide precursor A1. The weight-average molecular weight (estimated value) of A1 was 75,000.

### Synthesis Example 2 (Synthesis of Polyimide Precursor A2)

5.00 g of ODPA was dissolved in 58.2 g of NMP. 5.27 g of 1,3-bis[2-(4-aminophenyl)-2-propyl]benzene (Bisaniline P) was added thereto, and then the mixture was stirred at room temperature for 3 hours to obtain a polyimide precursor A2. The weight-average molecular weight (estimated value) of the polyimide precursor A2 was 75,000.

### Synthesis Example 3 (Synthesis of Polyimide Precursor A3)

5.00 g of bis(1,3-dioxo-1,3-dihydroisobenzofuran-5-carboxylic acid)1,4-phenylene (TAHQ) was dissolved in 52.4 g of NMP. 4.25 g of BAPP was added thereto, and then the mixture was stirred at room temperature for 3 hours to obtain a polyimide precursor A3. The weight-average molecular weight (estimated value) of the polyimide precursor A3 was 75,000.

### Synthesis Example 4 (Synthesis of Polyimide Precursor A4)

5.00 g of TAHQ was dissolved in 58.8 g of NMP. 5.37 g of 2,2-bis[4-(4-aminophenoxy)phenyl]hexafluoropropane (6F-BAPP) was added thereto, and then the mixture was stirred at room temperature for 5 hours to obtain a polyimide precursor A4. The weight-average molecular weight (estimated value) of the polyimide precursor A4 was 75,000.

### Synthesis Example 5 (Synthesis of Polyimide Precursor A5)

5.00 g of TAHQ was dissolved in 50.0 g of NMP. 3.82 g of 4,4′-bis(4-aminophenoxy)biphenyl (BAPB) was added thereto, and then the mixture was stirred at room temperature for 5 hours to obtain a polyimide precursor A5. The weight-average molecular weight (estimated value) of the polyimide precursor A5 was 75,000.

### Synthesis Comparative Example 1 (Synthesis of Polyimide Precursor A6)

12.1 g of BAPP and 0.08 g of 1,3-bis(3-aminopropyl)tetramethyldisiloxane (LP-7100) were dissolved in 90 g NMP. 10.00 g of 3,3′,4,4′-benzophenone tetracarboxylic dianhydride (BTDA) was added thereto, and the mixture was stirred for 60 minutes to obtain a polyimide precursor A6. The weight-average molecular weight (measured value) of the polyimide precursor A6 was measured by the method described in Synthesis Example 1, and was 95,000.

### Synthesis Comparative Example 2 (Synthesis of Polyimide Precursor A7)

1.51 g of 1,3-phenylenediamine (MPD) and 3.42 g of 4,4′-diaminodiphenyl ether (ODA) were dissolved in 60 g of NMP. Thereafter, 10.00 g of BTDA was added thereto, and the mixture was stirred for 60 minutes to obtain a polyimide precursor A7. The weight-average molecular weight (measured value) of the polyimide precursor A7 was measured by the method described in Synthesis Example 1, and was 53,000.

### Synthesis Comparative Example 3 (Synthesis of Polyimide Precursor A8)

13.00 g of 4,4′-oxydianiline (ODA), 0.88 g of 4,4′-diamino-3-carboxamido-diphenyl ether (DDEC), and 0.90 g of LP-7100 were dissolved in 140 g of NMP. Thereafter, 7.88 g of pyromellitic anhydride (PMDA) and 11.64 g of BTDA were added thereto, and the mixture was stirred for 60 minutes to obtain a polyimide precursor A8. The weight-average molecular weight (measured value) of the polyimide precursor A8 was measured by the method described in Synthesis Example 1, and was 108,000.

### Synthesis Comparative Example 4 (Synthesis of Polyimide Precursor A9)

5.00 g of PMDA was dissolved in 41.7 g of NMP. 2.35 g of 1,4-phenylenediamine (PPD) was added thereto, and then the mixture was stirred at room temperature for 3 hours to obtain a polyimide precursor A9. The weight-average molecular weight (estimated value) of the polyimide precursor A9 was 75,000.

### Synthesis Comparative Example 5 (Synthesis of Polyimide Precursor A10)

5.00 g of 4,4′-biphthalic anhydride (S-BPDA) was dissolved in 38.2 g of NMP. 1.75 g of PPD was added thereto, and then the mixture was stirred at room temperature for 3 hours to obtain a polyimide precursor A10. The weight-average molecular weight (measured value) of the polyimide precursor A10 was measured by the method described in Synthesis Example 1, and was 52,000.

### Synthesis Example 6 (Synthesis of Polyimide Precursor A11)

47.08 g of ODPA, 5.54 g of 2-hydroxyethyl methacrylate (HEMA), and 0.24 g of 1,4-diazabicyclo[2.2.2]octane were dissolved in 380 g of NMP, and the solution was stirred at 30° C. for 1 hours. A solution of 53.04 g of BAPP dissolved in 145 g of NMP was added thereto, and then the mixture was stirred at 30° C. for 3 hours. Then, the mixture was stirred at room temperature overnight to obtain a reaction solution. To this reaction solution, 59.70 g of trifluoroacetic anhydride was added, and the mixture was stirred at 45° C. for 3 hours. 40.37 g of HEMA and 0.08 g of benzoquinone were added thereto, and the mixture was stirred at 45° C. for 20 hours. The reaction solution was added dropwise to distilled water, and precipitates were collected by filtration and dried under reduced pressure to obtain a polyimide precursor A11. The weight-average molecular weight (measured value) of the polyimide precursor A11 was measured by the method described in Synthesis Example 1, and was 29,692

### [Measurement of Esterification Ratio]

The esterification ratio of the polyimide precursor A11 (i.e. the reaction ratio of the carboxy group of ODPA with HEMA) was obtained by measurement by the NMR under the following conditions, followed by calculation. The esterification ratio was 56 mol % or 68 mol % based on the total moles of carboxy groups and carboxy esters (the rest were carboxy groups).
Measurement instrument: AV400M manufactured by Bruker Japan K.K.
Magnetic field strength: 400 MHz.
Reference substance: tetramethylsilane (TMS)
Solvent: dimethylsulfoxide (DMSO)

### Synthesis Example 7 (Synthesis of Polyimide Precursor A12)

46.53 g of ODPA, 5.46 g of 2-hydroxyethyl methacrylate (HEMA), and 0.24 g of 1,4-diazabicyclo[2.2.2]octane were dissolved in 501.68 g of NMP and the mixture was stirred at 30° C. for 1 hours. 38.76 g of Bisaniline P was added thereto, and then the mixture was stirred at 30° C. for 3 hours. Then, the mixture was stirred at room temperature overnight to obtain a reaction solution. To this reaction solution, 58.91 g of trifluoroacetic anhydride was added, and the mixture was stirred at 45° C. for 3 hours. 39.81 g of HEMA and 0.09 g of benzoquinone were added thereto, and the reaction solution was stirred at 45° C. for 20 hours. The reaction solution was added dropwise to distilled water, and precipitates were collected by filtration and dried under reduced pressure to obtain a polyimide precursor A12. The weight-average molecular weight (measured value) of the polyimide precursor A12 was 24,800. The esterification ratio of the polyimide precursor A12 was measured in the same manner as in Synthesis Example 6, and was 53 mol %.

### Synthesis Example 8 (Synthesis of Polyimide Precursor A13)

23.54 g of ODPA, 2.77 g of 2-hydroxyethyl methacrylate (HEMA), and 0.12 g of 1,4-diazabicyclo[2.2.2]octane were dissolved in 250.00 g of NMP, and the mixture was stirred at 30° C. for 1 hours. A solution of 22.21 g of 1,3-bis[2-(4-aminophenyl)-2-propyl]benzene (Bisaniline M) dissolved in 108.75 g of NMP was added thereto, and then the mixture was stirred at 30° C. for 3 hours. Then, the mixture was stirred at room temperature overnight to obtain a reaction solution. To this reaction solution, 29.86 g of trifluoroacetic anhydride was added, and the mixture was stirred at 45° C. for 3 hours. 20.19 g of HEMA and 0.04 g of benzoquinone were added thereto, and the reaction solution was stirred at 45° C. for 20 hours. The reaction solution was added dropwise to distilled water, and precipitates were collected by filtration and dried under reduced pressure to obtain a polyimide precursor A13. The weight-average molecular weight (measured value) of the polyimide precursor A13 was 23,500. The esterification ratio of the polyimide precursor A13 was measured in the same manner as in Synthesis Example 6, and was 73 mol %.

### Synthesis Comparative Example 6 (Synthesis of Polyimide Precursor A14)

47.08 g of ODPA, 5.56 g of 2-hydroxyethyl methacrylate (HEMA), and 0.24 g of 1,4-diazabicyclo[2.2.2]octane were dissolved in 380.00 g of NMP, and the mixture was stirred at 30° C. for 1 hours. A solution of 27.44 g of m-tolidine (DMAP) dissolved in 145.00 g of NMP was added thereto, and then the mixture was stirred at 30° C. for 3 hours. Then, the mixture was stirred at room temperature overnight to obtain a reaction solution. To this reaction solution, 59.71 g of trifluoroacetic anhydride was added, and the mixture was stirred at 45° C. for 3 hours. 40.37 g of HEMA, and 0.08 g of benzoquinone were added thereto, and the reaction solution was stirred at 45° C. for 20 hours. The reaction solution was added dropwise to distilled water, and precipitates were collected by filtration and dried under reduced pressure to obtain a polyimide precursor A14. The weight-average molecular weight (measured value) of the polyimide precursor A14 was measured by the method described in Synthesis Example 1, and was 27,000. The esterification ratio of the polyimide precursor A14 was measured in the same manner as in Synthesis Example 6, and was 81 mol %.

Polyimide precursors A1 to A10 can be used as a resin material of a non-photosensitive resin composition, and polyimide precursors A11 to A14 can be used as a resin material of a photosensitive resin composition.

Each of the components used in the following Examples and Comparative Examples is shown below.

### (Component (A): Polyimide Precursor)

Polyimide precursors A1 to A14: polyimide precursors A1 to A14 obtained in Synthesis Examples and Synthesis Comparative Examples

### (Component (B): Polymerizable Monomer)

“TEGDMA” (manufactured by Shin-Nakamura Chemical Co., Ltd., triethylene glycol dimethacrylate, a compound represented by the following formula)

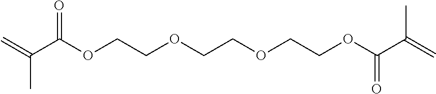 [SMILES: C=C(C)C(=O)OCCOCCOCCOC(=O)C(=C)C]

### (Component (C): Photopolymerization Initiator)

“IRGACURE OXE 02” (manufactured by BASF Japan Ltd., a compound represented by the following formula)

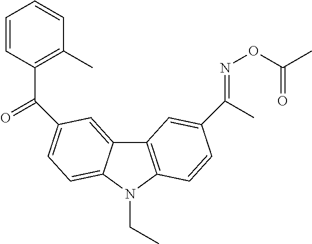 [SMILES: CCn1c2ccc(C(=O)c3ccccc3C)cc2c2cc(/C(C)=N/OC(C)=O)ccc21]

“G-1820 (PDO)” (manufactured by Lambson Ltd., a compound represented by the following formula)

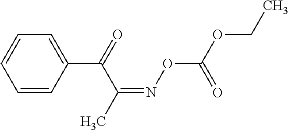 [SMILES: CCOC(=O)O/N=C(/C)C(=O)c1ccccc1]

### (Solvent)

NMP

### (Other Component: Sensitizer)

“EMK” (manufactured by Aldrich Corporation, a compound represented by the following formula, wherein Et represents an ethyl group)

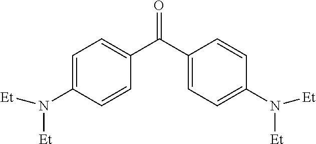 [SMILES: CCN(CC)c1ccc(C(=O)c2ccc(N(CC)CC)cc2)cc1]

### (Other Component: Rust Inhibitor)

“BT” (benzotriazole, a compound represented by the following formula, manufactured by Johoku Chemical CO., LTD)

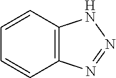

### (Other Component: Adhesive Aid)

“UCT-801” (3-ureidopropyltriethoxysilane, manufactured by United Chemical Technologies)

### (Other Component: Polymerization Inhibitor)

“Taobn” (1,4,4-trimethyl-2,3-diazabicyclo[3.2.2]-non-2-ene-N,N-dioxide, manufactured by Hampford Research)

### Examples 1 to 5 and Comparative Examples 1 to 5

Each of the solutions at the time of completion of synthesis in Synthesis Examples 1 to 5 and Synthesis Comparative Examples 1 to 5 (non-photosensitive resin composition) were used in each of the following steps.

### Preparation of Cured Film, Measurement of Relative Dielectric Constant Dk and Dielectric Loss Tangent Df

The obtained resin composition was applied on a wafer (manufactured by Advantech Co., Ltd.) and dried to form a resin film. Then, the resin film was cured by heating at the curing temperature shown in Table 1 to prepare a cured film. The curing time was 2 hours when the curing temperature was 200° C., 230° C., 250° C., or 320° C., and 1 hour when the curing temperature was 375° C.

Then, the cured film formed on the wafer was cut into a rectangular shape having a predetermined size using a cutter, and the cured film peeled from the wafer was served as a sample for measurement. The size of the cut-out cured film was a square shape of 6 cm×10 cm in the case where the measurement frequency was 5 GHz or 10 GHz, and was a square shape of3 cm×7 cm in the case when: the measurement frequency was 20 GHz. The film thickness of the sample for measurement is as shown in Table 1.

Using the obtained sample for measurement, the relative dielectric constant Dk and the dielectric loss tangent Df were measured by the following measurement method. The results are shown in Table 1.

### (Method for Measurement of the Relative Dielectric Constant Dk and the Dielectric Loss Tangent Df)

The resulting sample for measurement, was set in “SPDR dielectric resonator” manufactured by Agilent Technologies, Inc. and the relative dielectric constant Dk and the dielectric loss tangent Df were measured by SPDR method (split-post dielectric resonator method) at each frequency of 5 GHz, 10 GHz, and 20 GHz using vector network analyzer E8364B manufactured by Agilent Technologies, Inc. as measurement apparatus and CPMA-V2 as measurement program, respectively. Incidentally, the measurement temperature was 25° C. The relative dielectric constant Dk and the dielectric loss tangent Df shown in Table 1 are mean values of the measured values obtained by three measurements, respectively.

TABLE 1

| | | Cureing | Film | | | | | | |
|---|---|---|---|---|---|---|---|---|---|
| | Component (A) | temperature | Thickness | Dk (mean value) | | | Df (mean value) | | |
| | (acid/amine) | (° C.) | (μm) | 5 GHz | 10 GHz | 20 GHz | 5 GHz | 10 GHz | 20 GHz |
| Example 1 | A1 | 200 | 11.2 | 3.04 | 3.04 | 2.94 | 0.0029 | 0.0031 | 0.0035 |
| | (ODPA/BAPP) | 250 | 10.8 | 3.06 | 3.00 | 2.93 | 0.0028 | 0.0030 | 0.0034 |
| | | 320 | 10.6 | 3.07 | 3.00 | 3.01 | 0.0024 | 0.0029 | 0.0032 |
| | | 375 | 11.0 | 3.14 | 3.03 | 2.99 | 0.0030 | 0.0029 | 0.0034 |
| Example 2 | A2 | 200 | 10.5 | 3.06 | 3.06 | 2.87 | 0.0055 | 0.0053 | 0.0052 |
| | (ODPA/Bisaniline P) | | 10.0 | 2.99 | 3.04 | 2.96 | 0.0043 | 0.0043 | 0.0042 |
| | | 250 | 9.8 | 3.15 | 3.10 | 3.05 | 0.0033 | 0.0033 | 0.0033 |
| | | 320 | 10.6 | 3.06 | 3.10 | 2.94 | 0.0029 | 0.0030 | 0.0029 |
| | | | 10.3 | 2.94 | 2.96 | 2.80 | 0.0025 | 0.0029 | 0.0028 |
| | | 375 | 10.9 | 2.97 | 3.03 | 2.91 | 0.0027 | 0.0030 | 0.0029 |
| Example 3 | A3 | 250 | 7.3 | 3.19 | 3.09 | 3.11 | 0.0021 | 0.0023 | 0.0024 |
| | (TAHQ/BAPP) | 375 | 6.9 | 3.38 | 3.31 | 3.28 | 0.0023 | 0.0025 | 0.0027 |
| Example 4 | A4 | 200 | 11.3 | 3.12 | 3.19 | 2.98 | 0.0022 | 0.0032 | 0.0031 |
| | (TAHQ/BF-BAPP) | 375 | 11.5 | 2.96 | 3.03 | 2.96 | 0.0028 | 0.0034 | 0.0033 |
| Example 5 | A5 | 375 | 14.9 | 3.11 | 3.21 | 3.18 | 0.0020 | 0.0035 | 0.0035 |
| | (TAHQ/BAPB) | | | | | | | | |
| Comp. Ex. 1 | A6 | 250 | 12.5 | 3.50 | 3.45 | 3.28 | 0.0071 | 0.0071 | 0.0070 |
| | (BTDA/BAPP, LP-7100) | | | | | | | | |
| Comp. Ex. 2 | A7 | 200 | 10.0 | 3.59 | 3.65 | 3.43 | 0.0142 | 0.0181 | 0.0171 |
| | (BTDA/MPD, ODA) | | | | | | | | |
| Comp. Ex. 3 | A8 | 250 | 9.8 | 3.42 | 3.45 | 3.58 | 0.0155 | 0.0178 | 0.0179 |
| | (PMDA, BTDA/ODA, | | | | | | | | |
| | DDEC, LP-7100) | | | | | | | | |
| Comp. Ex. 4 | A9 | 375 | 8.0 | — | — | 3.49 | — | — | 0.0308 |
| | (PMDA/PPD) | | | | | | | | |
| Comp. Ex. 5 | A10 | 200 | 10.1 | 3.86 | 3.88 | 3.93 | 0.0184 | 0.0183 | 0.0170 |
| | (S-BPDA/PPD) | 230 | 9.5 | 3.69 | 3.83 | 3.77 | 0.0137 | 0.0134 | 0.0122 |
| | | 250 | 9.5 | 3.62 | 3.76 | 3.69 | 0.0110 | 0.0111 | 0.0099 |

From Table 1, it can be seen that the cured films obtained in Examples 1 to 5 have lower Dk and Df at each frequency of 5 GHz, 10 GHz, and 20 GHz than the cured films obtained in Comparative Examples 1 to 5, and can realize a small transmission loss even in a high frequency band. This effect becomes more clear when compared Comparative Example and Example to each other, which used the same curing conditions (wring time and wring temperature).

### Examples 6 to 14 and Comparative Example 6

### Preparation of Photosensitive Resin Composition

The photosensitive resin compositions of Examples 6 to 14 and Comparative Example 6 were prepared with the components and the blending amounts shown in Table 2, respectively. The blending amount shown in Table 2 is represented by parts by mass of each component based on 100 parts by mass of the component (A).

TABLE 2

| | | Example | | | | | | | | | Comp. |
|---|---|---|---|---|---|---|---|---|---|---|---|
| | | 6 | 7 | 8 | 9 | 10 | 11 | 12 | 13 | 14 | Ex 6 |
| Component | Resin used | A11 | A11 | A11 | A11 | A12 | A12 | A12 | A12 | A13 | A14 |
| (A) | (Esterification | (56%) | (68%) | (68%) | (68%) | (53%) | (53%) | (53%) | (53%) | (73%) | (81%) |
| | ratio) | | | | | | | | | | |
| Component | TEGDMA | 20 | 20 | 15 | 10 | 20 | 10 | 5 | 0 | 20 | 20 |
| (B) | | | | | | | | | | | |
| Component | I-OXE-02 | — | — | — | — | — | 2 | 2 | 2 | — | — |
| (C) | PDO | 9 | 9 | 9 | 9 | 9 | — | — | — | 9 | 9 |
| Other | EMK | 1.04 | 1.04 | 1.04 | 1.04 | 1.04 | — | — | — | 1.04 | 1.04 |
| component | BT | 2 | 2 | 2 | 2 | 2 | 2 | 2 | 2 | 2 | 2 |
| | UCT-801 | 6 | 6 | 6 | 6 | 6 | 6 | 6 | 6 | 6 | 6 |
| | NMP | 150 | 130 | 130 | 130 | 150 | 130 | 130 | 130 | 130 | 150 |
| | Taobn | 0.3 | 0.3 | 0.3 | 0.3 | 0.3 | 0.3 | 0.3 | 0.3 | 0.3 | 0.3 |

### [Formation of Patterned Cured Film, Measurements of Relative Dielectric Constant Dk and Dielectric Loss Tangent Df]

As to the obtained photosensitive resin compositions, the relative dielectric constant Dk and the dielectric loss tangent Df were measured in the same manner as in Examples 1 to 5 and Comparative Examples 1 to 5. The results are shown in Table 3.

TABLE 3

| | | Cureing | Film | | | | | | |
|---|---|---|---|---|---|---|---|---|---|
| | Component (A) | temperature | Thickness | Dk (mean value) | | | Df (mean value) | | |
| | (acid/amine) | (° C.) | (μm) | 5 GHz | 10 GHz | 20 GHz | 5 GHz | 10 GHz | 20 GHz |
| Example 6 | A11 | 200 | 10.5 | — | — | 2.96 | — | — | 0.0124 |
| | (ODPA(HEMA)/BAPP) | | 10.4 | — | — | 3.06 | — | — | 0.0122 |
| | | 250 | 9.9 | — | — | 2.92 | — | — | 0.0088 |
| | | 320 | 8.5 | — | — | 3.08 | — | — | 0.0053 |
| | | 375 | 10.5 | 3.22 | 3.21 | 3.03 | 0.0044 | 0.0044 | 0.0048 |
| Example 7 | A11 | 200 | 9.9 | — | — | 3.06 | — | — | 0.0147 |
| | (ODPA(HEMA)/BAPP) | 250 | 9.6 | — | — | 3.04 | — | — | 0.0141 |
| | | 320 | 8.1 | — | — | 3.11 | — | — | 0.0098 |
| Example 8 | A11 | 200 | 9.7 | — | — | 3.07 | — | — | 0.0138 |
| | (ODPA(HEMA)/BAPP) | 250 | 9.4 | — | — | 3.04 | — | — | 0.0128 |
| | | 320 | 8.3 | — | — | 3.11 | — | — | 0.0098 |
| Example 9 | A11 | 200 | 9.5 | — | — | 3.08 | — | — | 0.0118 |
| | (ODPA(HEMA)/BAPP) | 250 | 9.3 | — | — | 3.03 | — | — | 0.0107 |
| | | 320 | 8.6 | — | — | 2.93 | — | — | 0.0082 |
| Example 10 | A12 | 200 | 9.6 | 3.01 | 3.10 | 2.96 | 0.0136 | 0.0126 | 0.0113 |
| | (ODPA(HEMA)/ | 250 | 9.1 | 3.10 | 3.09 | 3.08 | 0.0111 | 0.0110 | 0.0105 |
| | Bisaniline P) | 375 | 10.9 | 3.07 | 3.09 | 2.96 | 0.0043 | 0.0042 | 0.0038 |
| Example 11 | A12 | 200 | 9.3 | — | — | 2.97 | — | — | 0.0128 |
| | (ODPA(HEMA)/ | 250 | 9.2 | — | — | 2.94 | — | — | 0.0112 |
| | Bisaniline P) | 320 | 8.7 | — | — | 2.85 | — | — | 0.0088 |
| Example 12 | A12 | 200 | 9.3 | — | — | 2.89 | — | — | 0.0108 |
| | (ODPA(HEMA)/ | 250 | 8.6 | — | — | 2.99 | — | — | 0.0096 |
| | Bisaniline P) | 320 | 8.5 | — | — | 2.92 | — | — | 0.0074 |
| Example 13 | A12 | 200 | 8.5 | — | — | 3.04 | — | — | 0.0093 |
| | (ODPA(HEMA)/ | 250 | 8.5 | — | — | 2.91 | — | — | 0.0073 |
| | Bisaniline P) | 320 | 8.0 | — | — | 2.97 | — | — | 0.0062 |
| Example 14 | A13 | 200 | 10.2 | 3.05 | 3.06 | 2.93 | 0.0138 | 0.0134 | 0.0118 |
| | (ODPA(HEMA)/ | 250 | 9.7 | 3.08 | 3.07 | 2.94 | 0.0119 | 0.0114 | 0.0101 |
| | Bisaniline M) | 375 | 11.3 | 3.07 | 3.05 | 2.99 | 0.0031 | 0.0031 | 0.0030 |
| Comp. Ex. 6 | A14 | 375 | 10.0 | — | 3.29 | 3.30 | — | 0.0090 | 0.0150 |
| | (ODPA(HEMA)/DMAP) | | | | | | | | |

From Table 3, it can be seen that the cured films obtained in Examples 6 to 14 have lower Dk and Df at each frequency of 5 GHz, 10 GHz, and 20 GHz than the cured films obtained in Comparative Example 6, and can realize a small transmission loss even in a high frequency band. This effect becomes more clear when compared Comparative Example and Example to each other, which used the same curing conditions (curing time and curing temperature).

### INDUSTRIAL APPLICABILITY

The photosensitive resin composition of the invention can be used for formation of an interlayer insulating film, a cover coat layer, a surface protective film, or the like, and the interlayer insulating film, the cover coat layer, or the surface protective film of the invention can be used for an electronic component or the like.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

All the contents of the document described heroin are incorporated by reference.

1. A polyimide precursor having a structural unit represented by the following formula (1): 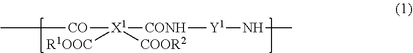
wherein in the formula (1), X¹ is a tetravalent group having one or more aromatic groups;
and when X¹ is a group represented by the following formula (11), Z³ is a divalent group other than a carbonyl group; 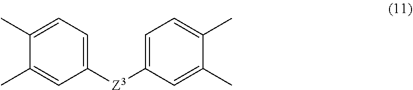
Y¹ is a divalent group obtained by linking one or more kinds of groups selected from the group consisting of divalent groups represented by each of the following formulas (21) to (24); 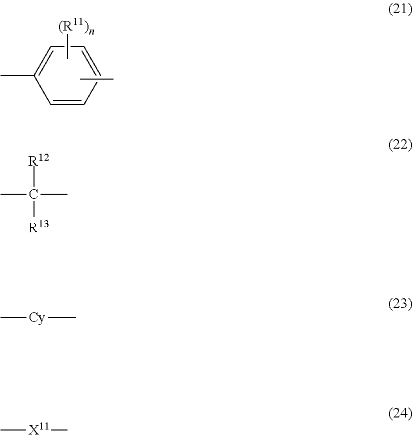
wherein in the formula (21), R¹¹ is an aliphatic hydrocarbon group including 1 to 4 carbon atoms, or a halogenated aliphatic hydrocarbon group including 1 to 4 carbon atoms; and n is an integer of 0 to 4;
wherein in the formula (22), R¹² and R¹³ are independently a hydrogen atom, an aliphatic hydrocarbon group including 1 to 4 carbon atoms, or a halogenated aliphatic hydrocarbon group including 1 to 4 carbon atoms;
wherein in the formula (23), Cy is an alicyclic hydrocarbon group including 3 to 10 carbon atoms;
wherein in the formula (24), X¹¹ is an oxygen atom or a sulfur atom;
when in Y¹, the number of divalent group represented by the formula (21) is e, the number of divalent group represented by the formula (22) is f, the number of divalent group represented by the formula (23) is g, and the number of divalent group represented by the formula (24) is h, e≥1, f≥0, g≥0, and h≥0, and e+f+g+h>4;
R¹ and R² are independently a hydrogen atom, a group represented by the following formula (2), or an aliphatic hydrocarbon group including 1 to 4 carbon atoms; 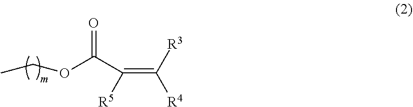
wherein in the formula (2), R³ to R⁵ are independently a hydrogen atom or an aliphatic hydrocarbon group including 1 to 4 carbon atoms, and m is an integer of 1 to 10;
a —COOR¹ group and a —CO— group are in ortho-position to each other, and a —COOR² group and a —CONH— group are in ortho-position to each other.

2. The polyimide precursor according to claim 1, wherein Y¹ comprises the divalent group represented by the formula (21) and the divalent group represented by the formula (22).

3. The polyimide precursor according to claim 1, wherein Y¹ comprises the divalent group represented by the formula (21) and the divalent group represented by the formula (24).

4. The polyimide precursor according to claim 1, wherein Y¹ comprises the divalent group represented by the formula (21), the divalent group represented by the formula (22), and the divalent group represented by the formula (24).

5. The polyimide precursor according to claim 1, wherein in the formula (1), e≥3.

6. The polyimide precursor according to claim 1, wherein in the formula (1), e≥3 and f≥2.

7. The polyimide precursor according claim 1, wherein in the formula (1), e≥3 and h≥2.

8. The polyimide precursor according to claim 1, wherein in the formula (1), e≥4.

9. The polyimide precursor according to claim 1, wherein in the formula (1), e+f+g+h≥5.

10. The polyimide precursor according to claim 1, wherein in the formula (21), n=0.

11. The polyimide precursor according to claim 1, wherein in the formula (22), R¹² and R¹³ are independently a methyl group or a trifluoromethyl group.

12. The polyimide precursor according to claim 1, wherein in the formula (24), X¹¹ is an oxygen atom.

13. The polyimide precursor according to claim 1, wherein Y¹ comprises a divalent group represented by the following formula (31) or (32): 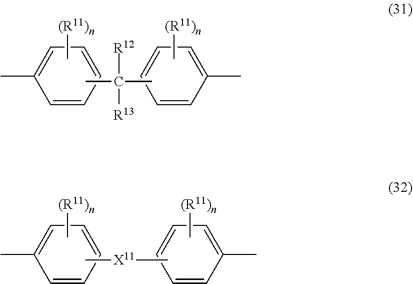
wherein in the formulas (31) and (32), R¹¹, n, R¹², R¹³, and X¹¹ are as defined in each of the formulas (21), (22), and (24).

14. The polyimide precursor according to claim 1, wherein Y¹ comprises any of the divalent groups represented by each of the following formulas:

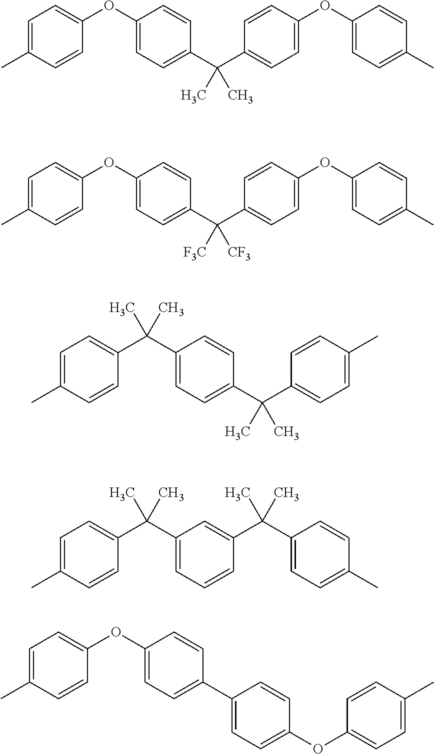

15. The polyimide precursor according to claim 1, wherein X¹ is any of the tetravalent groups represented by each of the following formulas: 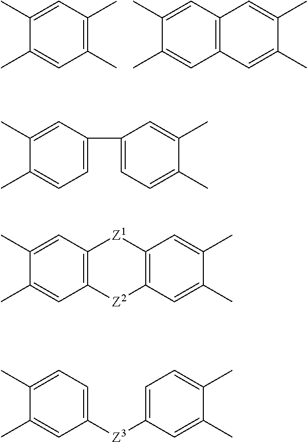
Z¹ and Z² are independently a divalent group which does not conjugate with the benzene rings bonded thereto, or a single bond; and Z³ is a divalent group other than a carbonyl group.

16. The polyimide precursor according to claim 1, wherein Z³ comprises an ether bond (—O—) or a sulfide bond (—S—).

17. The polyimide precursor according to claim 1, wherein Z³ comprises a divalent group having an aromatic hydrocarbon group.

18. The polyimide precursor according to claim 1, wherein Z³ comprises a divalent group represented by —O—Ar—O—, —S—Ar—S—, or —COO—Ar—OOC—, wherein Ar is a divalent group comprising a benzene ring, a divalent group comprising a naphthalene ring, or a divalent group comprising an anthracene ring.

19. The polyimide precursor according to claim 1, wherein in the formula (1), R¹ and R² are independently a hydrogen atom or an aliphatic hydrocarbon group including 1 to 4 carbon atoms.

20. The polyimide precursor according to claim 1, wherein in the formula (1), at least one of R¹ and R² is a monovalent group represented by the formula (2).

21. A resin composition comprising the polyimide precursor according to claim 1.

22. A photosensitive resin composition comprising:
(A) the polyimide precursor according to claim 1,
(B) a polymerizable monomer; and
(C) a photopolymerization initiator.

23. A method for manufacturing a patterned cured film comprising a step of applying the photosensitive resin composition according to claim 22 on a substrate, followed by drying to form a photosensitive resin film
subjecting the photosensitive resin film to pattern-exposure to obtain a resin film;
developing the resin film having undergone the pattern-exposure using an organic solvent to obtain a patterned resin film; and
heat-treating the patterned resin film.

24. The method for manufacturing a patterned cured film according to claim 23, wherein the heat treatment is conducted at a temperature of 200° C. or less.

25. A cured film obtained by curing the photosensitive resin composition according to claim 22.

26. The cured film according to claim 25, which is a patterned cured film.

27. An interlayer insulating film, a cover coat layer, or a surface protective film formed by using the cured film according to claim 25.

28. An electronic component comprising the interlayer insulating film, the cover coat layer, or the surface protective film according to claim 27.
